(19) United States
(12) Patent Application Publication
(10) Pub. No.: US 2025/0212632 A1
(43) Pub. Date: Jun. 26, 2025

(54) DISPLAY DEVICE

(71) Applicant: LG Display Co., Ltd., Seoul (KR)

(72) Inventors: Heejoong KIM, Paju-si (KR); Yujin LEE, Paju-si (KR)

(73) Assignee: LG Display Co., Ltd., Seoul (KR)

(21) Appl. No.: 18/919,000

(22) Filed: Oct. 17, 2024

(30) Foreign Application Priority Data
Dec. 20, 2023 (KR) 10-2023-0187342

(51) Int. Cl. H10K 59/131; H10K 59/12; H10K 59/126; H10K 59/35; H10K 59/80; H10K 71/00

(52) U.S. Cl. CPC H10K 59/131; H10K 59/126; H10K 59/8791; H10K 59/1201; H10K 59/351; H10K 71/861

(57) ABSTRACT

Embodiments relate to a display device including a substrate which includes an emission area and a non-emission area of a sub-pixel and on which a plurality of sub-pixels are disposed, a gate line disposed in the non-emission area and extending in one direction, a signal line disposed in the non-emission area and intersecting the gate line, a repair pattern disposed in the non-emission area and connected to the signal line, and at least one branch line for connecting the repair pattern with circuit devices of the plurality of sub-pixels.

### CROSS REFERENCE TO RELATED APPLICATION

The present application claims priority to Korean Patent Application No. 10-2023-0187342, filed on Dec. 20, 2023, the entire contents of which is incorporated herein for all purposes by this reference.

### BACKGROUND

### Technical Field

The present invention relates to a display device, and more specifically, to a display device capable of implementing a high aperture ratio and stably performing pixel repair.

### Discussion of the Related Art

As the information society develops, various demands for display devices for displaying images are increasing, and various types of display devices such as liquid crystal displays (LCDs) and organic light emitting diode (OLED) displays are utilized.

The display device includes a display panel on which pixels are disposed, a gate driver for supplying gate signals to the pixels through gate lines, a data driver for applying data signals to the pixels through data lines, and a timing controller for controlling operations of the gate driver and the data driver.

### SUMMARY

Accordingly, embodiments of the present disclosure are directed to a display device that substantially obviates one or more of the problems due to limitations and disadvantages of the related art.

An aspect of the present disclosure is to provide a display device disposed in an area in which an aperture ratio can be increased by changing a structure of a transparent branch line connected to a reference voltage line.

Another aspect of the present disclosure is to provide a display device in which an aperture ratio is increased and a lifetime of image sticking is increased by reducing an area in which a color filter is disposed.

Another aspect of the present disclosure is to provide a display device capable of performing a repair process without reducing an aperture ratio.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display device may comprise a substrate which includes an emission area and a non-emission area of a sub-pixel and on which a plurality of sub-pixels are disposed, a gate line disposed in the non-emission area and extending in one direction, a signal line disposed in the non-emission area and intersecting the gate line, a repair pattern disposed in the non-emission area and connected to the signal line, and at least one branch line for connecting the repair pattern with circuit devices of the plurality of sub-pixels.

The at least one branch line may be made of a transparent material.

At least one area of the at least one branch line may overlap the emission areas of the plurality of sub-pixels.

The repair pattern may include a body portion connected to the signal line, and a plurality of extensions extending in one direction from the body portion and connected to the plurality of sub-pixels, respectively.

At least some of the plurality of extensions may be connected to the plurality of sub-pixels, respectively, through the at least one branch line.

At least some of the plurality of extensions may extend from one side of the body portion and may be disposed in a first color sub-pixel disposed at one side of the body portion.

The others of the plurality of extensions may extend from the other side of the body portion and may be disposed in a second color sub-pixel disposed at the other side of the body portion.

The plurality of extensions may be cut with a laser upon pixel repair.

The display device may further include a color filter layer disposed in the emission area and extending to the non-emission area to cover at least one area of the repair pattern.

The color filter layer may include a first color filter formed in the emission area of a first color sub-pixel disposed at one side of the repair pattern and extending to the non-emission areas of adjacent sub-pixels of the first color sub-pixel.

The first color filter may cover at least one of the plurality of extensions of the repair pattern in the non-emission area of an adjacent second color sub-pixel.

The first color sub-pixel may be a blue sub-pixel, the second color sub-pixel may be a white sub-pixel, and the first color filter is a blue color filter.

The display device may further include a first conductive layer formed on the substrate and including the signal line, a buffer layer formed on the first conductive layer, an active layer formed on the buffer layer and including the at least one branch line, an interlayer insulating layer formed on the active layer, and a second conductive layer formed on the interlayer insulating layer and including the gate line and the repair pattern.

In another aspect, a display device may comprise a substrate which includes an emission area and a non-emission area of a sub-pixel and on which a plurality of sub-pixels are disposed, a gate line disposed in the non-emission area and extending in one direction, a signal line disposed in the non-emission area and intersecting the gate line, and a repair pattern disposed in the non-emission area and for connecting the signal line with circuit devices of the plurality of sub-pixels.

The repair pattern may include a body portion connected to the signal line, and a plurality of extensions extending in one direction from the body portion and connected to the plurality of sub-pixels, respectively.

At least some of the plurality of extensions may extend from one side of the body portion and may be disposed in a blue sub-pixel disposed at one side of the body portion.

The others of the plurality of extensions may extend from the other side of the body portion and may be disposed in a white sub-pixel disposed at the other side of the body portion.

The display device may include a blue color filter formed in the emission area of the blue sub-pixel and extending to the non-emission areas of adjacent sub-pixels of the blue sub-pixel.

The blue color filter may cover at least one of the plurality of extensions of the repair pattern in the non-emission area of an adjacent white sub-pixel.

In one embodiment, the repair pattern and branch line shape are specially configured to perform pixel repair in the blue pixel.

By reducing the blue color filter placement area, the pixel aperture ratio is increased and the afterimage life is increased.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain various principles.

FIG. 1 is a block diagram showing a display device according to one embodiment.

FIG. 2 is a circuit diagram of a sub-pixel according to one embodiment.

FIGS. 3 to 5 are plan views of unit pixels according to one embodiment.

FIG. 6 is an enlarged view of area AA shown in FIG. 5.

FIG. 7 is one embodiment of a cross-sectional view along line I-I′ in FIG. 5.

FIG. 8 is one embodiment of a cross-sectional view along line II-II′ in FIG. 6.

FIG. 9 is a cross-sectional view for describing a pixel repair method according to one embodiment.

### DETAILED DESCRIPTION

Hereinafter, embodiments will be described with reference to the accompanying drawings. In the specification, when a first component (or an area, a layer, a portion, or the like) is described as “on,” “connected,” or “coupled to” a second component, it means that the first component may be directly connected/coupled to the second component or a third component may be disposed therebetween.

The same reference numerals indicate the same components. In addition, in the drawings, thicknesses, proportions, and dimensions of components are exaggerated for effective description of technical contents. The term “and/or” includes all one or more combinations that may be defined by the associated configurations.

Terms such as first and second may be used to describe various components, but the components are not limited by the terms. The terms are used only for the purpose of distinguishing one component from another. For example, a first component may be referred to as a second component, and similarly, the second component may also be referred to as the first component without departing from the scopes of the embodiments. The singular expression includes the plural expression unless the context clearly dictates otherwise.

Terms such as “under,” “at a lower side,” “above,” and “at an upper side” are used to describe the relationship between the components illustrated in the drawings. The terms are relative concepts and are described with respect to directions marked in the drawings.

It should be understood that term such as “includes” or “has” is intended to specify the presence of features, numbers, steps, operations, components, parts, or a combination thereof described in the specification and does not preclude the presence or addition possibility of one or more other features, numbers, steps, operations, components, parts, or combinations thereof in advance.

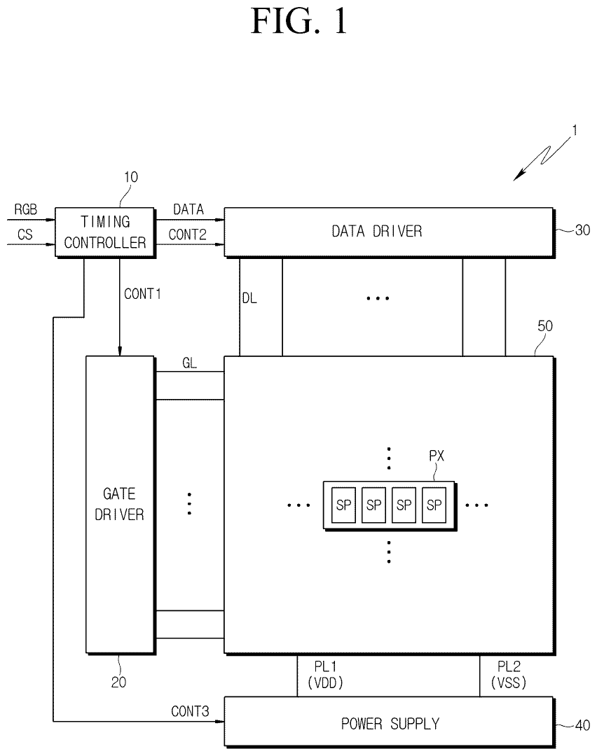

FIG. 1 is a block diagram showing a display device according to one embodiment.

Referring to FIG. 1, a display device 1 includes a timing controller 10, a gate driver 20, a data driver 30, a power supply 40, and a display panel 50.

The timing controller 10 may receive image signals RGB and a control signal CS from an external host system (not shown) or the like. The image signals RGB may include a plurality of grayscale data. The control signal CS may include, for example, a horizontal synchronization signal, a vertical synchronization signal, a main clock signal, and the like.

The timing controller 10 may process the image signals RGB and the control signal CS according to operating conditions of the display panel 50, and generate and output image data DATA, a gate driving control signal CONT1, a data driving control signal CONT2, and a power supply control signal CONT3.

The gate driver 20 may generate gate signals based on a gate driving control signal CONT1 output from the timing controller 10. The gate driver 20 may provide the generated gate signals to sub-pixels SP through a plurality of gate lines GL.

The data driver 30 may generate data signals based on the image data DATA and the data driving control signal CONT2 output from the timing controller 10. The data driver 30 may provide the generated data signals to the sub-pixels SP through a plurality of data lines DL.

The power supply 40 may generate a high potential driving voltage VDD and a low potential driving voltage VSS to be provided to the display panel 50 based on the power supply control signal CONT3. The power supply 40 may provide the generated driving voltages VDD and VSS to the sub-pixels SP through the corresponding power lines PL1 and PL2.

A plurality of unit pixels PX are disposed on the display panel 50. Each unit pixel PX may be composed of a plurality of sub-pixels SP. Each sub-pixel SP may display any one of red, green, blue, and white. In another embodiment, each sub-pixel SP may display any one of cyan, magenta, and yellow.

The sub-pixels SP may charge data voltages supplied through the data lines DL in response to the gate signals applied through the gate lines GL and emit light with brightness corresponding to the charged data voltage.

The timing controller 10, the gate driver 20, the data driver 30, and the power supply 40 may each be configured as a separate integrated circuit (IC) or at least a partially integrated IC. In addition, the gate driver 20 may be configured in a form of a gate in panel formed integrally with the display panel 50. In the embodiment, the gate driver 20 may constitute a gate-in-panel (hereinafter referred to as “GIP”).

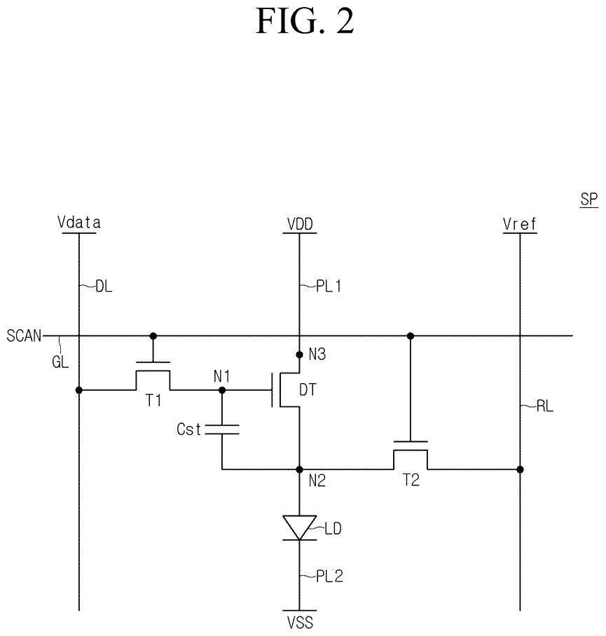

FIG. 2 is a circuit diagram of a sub-pixel according to one embodiment.

Referring to FIG. 2, the sub-pixel SP according to one embodiment may include a driving transistor DT, a light emitting device LD connected to the driving transistor DT, and a control circuit for controlling the amount of driving current to be applied to the light emitting device LD through the driving transistor DT. For example, the control circuit may include first and second transistors T1 and T2 and a storage capacitor Cst.

The driving transistor DT controls the driving current applied to the light emitting device LD according to a voltage between a gate and a source. A first electrode (e.g., a drain electrode) of the driving transistor DT is connected to the first power line PL1 to which the high potential driving voltage VDD is applied through a third node N3, and a second electrode (e.g., a source electrode) is connected to a second node N2. The gate electrode of the driving transistor DT is connected to a first node N1. The driving transistor DT may be turned on according to a voltage applied to the first node N1 to control the amount of driving current flowing to the light emitting device LD.

A first transistor T1 is a switching transistor and is connected between the data line DL and the first node N1. A gate electrode of the first transistor T1 is connected to the gate line GL. The first transistor T1 may be turned on in response to a scan signal SCAN applied to the gate line GL. When the first transistor T1 is turned on, a data voltage Vdata applied to the data line DL may be applied to the first node N1. The first transistor T1 may be electrically connected to the gate electrode of the driving transistor DT to apply the data voltage Vdata to the gate electrode of the driving transistor DT.

A storage capacitor Cst is connected between the first node N1 and the second node N2. The storage capacitor Cst may maintain a constant gate-source voltage of the driving transistor DT for one frame by storing a voltage corresponding to a voltage difference between the first node N1 and the second node N2.

The light emitting device LD may have an anode electrode connected to the second node N2 and a cathode electrode connected to the second power line PL2 to which the low potential driving voltage VSS is applied. When the driving transistor DT is turned on, a current path may be formed between the high potential driving voltage VDD and the low potential driving voltage VSS so that the driving current may flow to the light emitting device LD. The light emitting device LD may emit light with brightness corresponding to the amount of driving current applied.

Meanwhile, as a driving time of each sub-pixel SP in the display device 1 increases, circuit devices such as the driving transistor DT can be degraded. Therefore, unique characteristic values of the circuit devices may be changed. Here, the characteristic values of the circuit devices may include a threshold voltage (Vth), mobility (a), and the like. A change in characteristic values of the circuit devices may cause a change in brightness of the corresponding sub-pixel SP.

In addition, a degree of change in characteristic values of the circuit devices of each sub-pixel SP may be different depending on a degree of degradation of each sub-pixel SP. A difference in the degrees of change in characteristic values may cause brightness deviation between the sub-pixels SP.

To solve such a problem, the sub-pixel SP may be further provided with a circuit device capable of sensing the characteristic value of the sub-pixel SP. Specifically, as shown in FIG. 2, the sub-pixel SP may further include a second transistor T2.

The second transistor T2 is a sensing transistor and is connected between the second node N2 and a reference voltage line RL to which a reference voltage Vref is applied. A gate electrode of the second transistor T2 is connected to the gate line GL. The second transistor T2 may be turned on in response to the scan signal SCAN applied to the gate line GL and may connect the second node N2 with the reference voltage line RL.

The second transistor T2 may be turned on by the scan signal SCAN applied through the gate line GL and may apply the reference voltage Vref supplied through the reference voltage line RL to the source electrode of the driving transistor DT. In addition, the second transistor T2 can be used as one of voltage sensing paths for the source electrode of the driving transistor DT.

In the embodiment shown in FIG. 2, the transistors of the sub-pixel SP are n-type transistors and may be formed of oxide semiconductor thin film transistors. The oxide semiconductor thin film transistor includes a gate electrode, a source electrode, and a drain electrode. The oxide semiconductor thin film transistor has an active layer formed of an oxide semiconductor. Here, the oxide semiconductor may be set to an amorphous or crystalline oxide semiconductor. The oxide semiconductor thin film transistor may be formed of an n-type transistor. The oxide semiconductor thin film transistor may be processed at low temperatures and has lower charge mobility than a low temperature poly silicone (LTPS) thin film transistor. The oxide semiconductor thin film transistor has excellent off-current characteristics.

However, the present embodiment is not limited thereto. In other words, in another embodiment, one or more transistors of the sub-pixel SP may be LTPS thin film transistors. The LTPS thin film transistor includes a gate electrode, a source electrode, and a drain electrode. The LTPS thin film transistor has an active layer made of polysilicon. The LTPS thin film transistor has high electron mobility, and thus has fast driving characteristics. The LTPS thin film transistor may be formed of a p-type thin film transistor or an n-type thin film transistor.

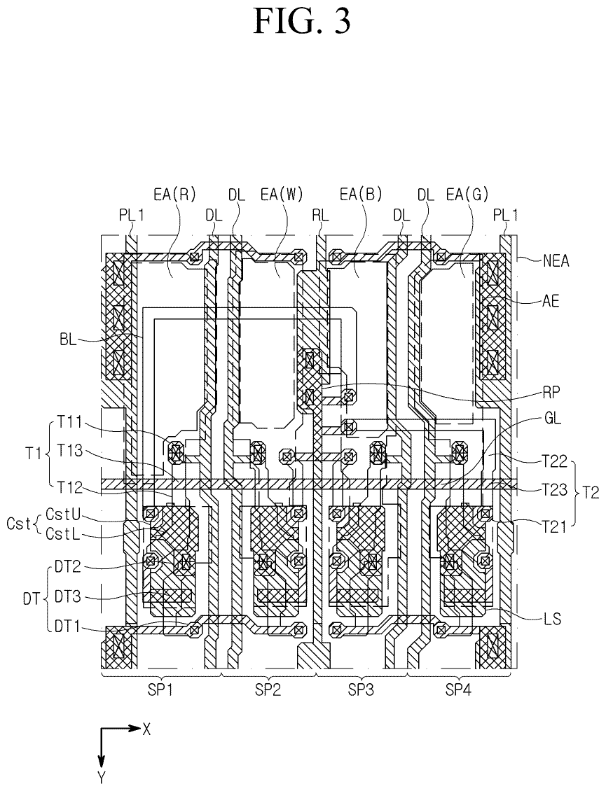

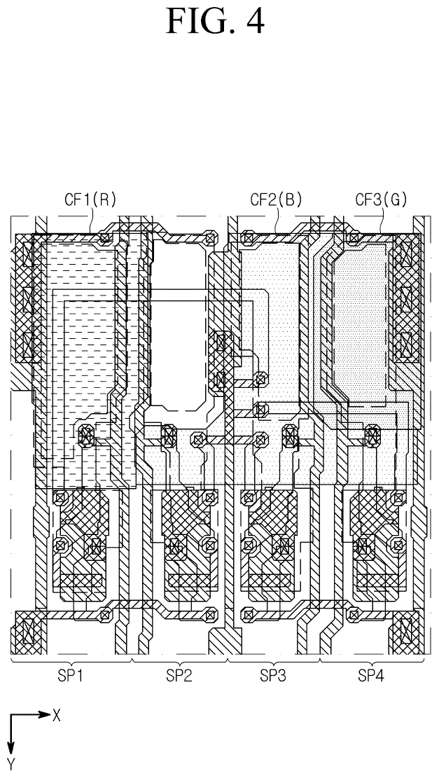

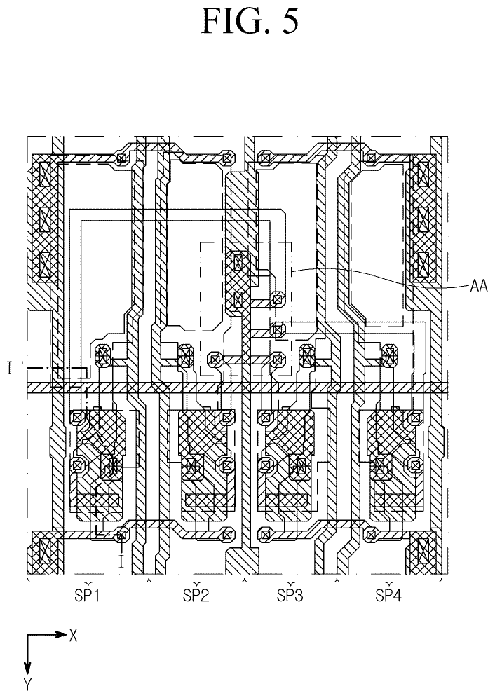

FIGS. 3 to 5 are plan views of unit pixels according to one embodiment. Specifically, FIGS. 3 to 5 show plan layouts of the sub-pixel SP shown in FIG. 2. FIG. 3 shows plan layers for the circuit devices of the sub-pixel SP, FIG. 4 shows an example in which a color filter and an anode electrode are further disposed on the circuit devices of the sub-pixel SP, and FIG. 5 includes area markings and cut lines on the plan layout.

Referring to FIGS. 3 to 5, in one embodiment, one unit pixel PX may be composed of four sub-pixels SP1, SP2, SP3, and SP4. A first sub-pixel SP1 may be a red sub-pixel displaying red, a second sub-pixel SP2 may be a white sub-pixel displaying white, a third sub-pixel SP3 may be a blue sub-pixel displaying blue, and a fourth sub-pixel SP4 may be a green sub-pixel displaying green. However, the present embodiment is not limited thereto.

Each of the sub-pixels SP1, SP2, SP3, and SP4 may be formed in an area defined by the gate line GL extending in a row direction X (first direction) and the data line DL extending in a column direction Y (second direction). The first power line (for example the high potential voltage line) PL1 and the reference voltage line RL may extend substantially parallel to the data line DL.

In one embodiment, two or more sub-pixels SP1, SP2, SP3, and SP4 adjacent in the row direction X may share one first power line PL1 and/or one reference voltage line RL. For example, the first power line PL1 may be disposed at one side of the first sub-pixel SP1 to apply the high potential driving voltage VDD to the first sub-pixel SP1 and the second sub-pixel SP2. Alternatively, for example, the first power line PL1 may be disposed at one side of the fourth sub-pixel SP4 to apply the high potential driving voltage VDD to the third sub-pixel SP3 and the fourth sub-pixel SP4. In addition, for example, one reference voltage line RL may be disposed in the unit pixel PX, and the sub-pixels SP1, SP2, SP3, and SP4 forming the unit pixel PX may share one reference voltage line RL.

Each of the sub-pixels SP1, SP2, SP3, and SP4 includes a non-emission area NEA and an emission area EA.

The non-emission area NEA is an area where the driving circuit for driving the light emitting device LD is disposed, and the driving transistor DT (see FIG. 2), the first transistor T1 (see FIG. 2), the second transistor T2 (see FIG. 2), and the storage capacitor Cst (see FIG. 2) may be disposed in the non-emission area NEA.

In the following description, source electrodes and drain electrodes of the transistors DT, T1, and T2 may indicate conductive source areas and drain areas of the active layer or indicate a conductive pattern electrically connected to the source areas and the drain areas. In addition, each of the nodes N1 to N3 is a connection point of two or more circuit devices and may indicate one point or area on a pattern.

A first electrode DT1 (e.g., a drain electrode) of the driving transistor DT is connected to the first power line PL1. In one embodiment, the first electrodes DT1 of the two or more sub-pixels SP1, SP2, SP3, and SP4 adjacent in the row direction X may be formed integrally. For example, the first electrode DT1 of the first sub-pixel SP1 and the first electrode DT1 of the second sub-pixel SP2 may be formed in one pattern and connected to one first power line PL1, and the first electrode DT1 of the third sub-pixel SP3 and the first electrode DT1 of the fourth sub-pixel SP4 are formed in one pattern and connected to one first power line PL1. A second electrode DT2 (e.g., a source electrode) of the driving transistor DT is connected to the second node N2. A gate electrode DT3 of the driving transistor DT is connected to the first node N1.

The storage capacitor Cst is connected between the first node N1 and the second node N2. This storage capacitor Cst may include a lower electrode CstL connected to the first node N1 and an upper electrode CstU connected to the second node N2. The lower electrode CstL of the storage capacitor Cst may be formed in a planar pattern connected to the gate electrode DT3 of the driving transistor DT. The upper electrode CstU of the storage capacitor Cst may be formed integrally with the second electrode DT2 of the driving transistor DT and may be formed in a pattern on a wide surface. The lower electrode CstL and the upper electrode CstU of the storage capacitor Cst may be disposed to overlap each other, and capacitance may be formed therebetween.

A first electrode T11 (e.g., a source electrode) of the first transistor T1 is connected to the data line DL. A second electrode T12 (e.g., a drain electrode) of the first transistor T1 is connected to the first node N1. The second electrode T12 of the first transistor T1 is a conductive area of the active layer and may be formed integrally with the lower electrode CstL of the storage capacitor Cst. In addition, the second electrode T12 of the first transistor T1 may be connected to the gate electrode DT3 of the driving transistor DT via the lower electrode CstL of the storage capacitor Cst. A gate electrode T13 of the first transistor T1 is connected to the gate line GL.

A first electrode T21 (e.g., a source electrode) of the second transistor T2 is connected to the second node N2. The first electrode T21 of the second transistor T2 may be formed integrally with the second electrode DT2 of the driving transistor DT and the upper electrode CstU of the storage capacitor Cst.

A second electrode T22 (e.g., a drain electrode) of the second transistor T2 is a conductive area of the active layer and is connected to the reference voltage line RL. As described above, when the four sub-pixels SP1, SP2, SP3, and SP4 share one reference voltage line RL in the unit pixel PX, a branch line BL may be further provided to connect the sub-pixels SP1 and SP4 disposed far from the reference voltage line RL to the reference voltage line RL. For example, the first sub-pixel SP1 and the fourth sub-pixel SP4 may each be connected to the reference voltage line RL through the branch line BL extending from the reference voltage line RL toward the first sub-pixel SP1 and the fourth sub-pixel SP4. One side of the branch line BL may be connected to the reference voltage line RL, and the other side may be connected to the second electrode T22 of the second transistor T2 of the connected sub-pixels SP1 and SP4.

To connect the reference voltage line RL with each of the sub-pixels SP1 and SP4, the reference voltage line RL may have a bar shape in which at least one area extends and include one or more bent or curved portions. Specifically, the branch line BL may have an “L” shape in which at least one area is bent after extending in the row direction X and extends in the column direction Y, but is not limited thereto.

In one embodiment, the branch line BL may be formed as a single pattern integrated with the second electrode T22 of the second transistor T2 of the corresponding sub-pixels SP1 and SP4. However, the present embodiment is not limited thereto, and the branch line BL may be configured in a form of a bridge for connecting one or more different layers.

In one embodiment, at least a portion of the extended area of the branch line BL may be disposed to overlap the emission areas EAs of the sub-pixels SP1, SP2, SP3, and SP4. In other words, at least a portion of the branch line BL may extend to cross the emission areas EAs of the sub-pixels SP1, SP2, SP3, and SP4.

For example, the branch line BL may extend to cross the emission areas EAs of the first and second sub-pixels SP1 and SP2 and may be connected to the first sub-pixel SP1. In this case, a bent portion of the branch line BL may be disposed in the emission area EA of the first sub-pixel SP1, but is not limited thereto. In the embodiment, the branch line BL may be made of a transparent material to prevent light emitted from the light emitting device LD from being shielded.

When the branch line BL is made of an opaque material, the branch line BL should be disposed in the non-emission area NEA so as not to block an optical path. When an area of the non-emission area NEA increases to secure a space in which the branch line BL is disposed, an area, that is, an aperture ratio of the emission area EA decreases relatively. As described above, when the branch line BL is made of a transparent material, the branch line BL may be disposed in the emission area EA, and thus it is possible to secure a sufficient aperture ratio of the emission area EA.

A gate electrode T23 of the second transistor T2 is connected to the gate line GL.

Meanwhile, a light shielding layer LS may be provided under the driving transistor DT and the storage capacitor Cst. The light shielding layer LS may be provided to shield outside light which may flow into a semiconductor layer. The light shielding layer LS may be disposed only under the driving transistor DT or under other circuit devices. The light shielding layer LS may shield outside light, assist connection between other electrodes and lines, or can be used as the electrode of the storage capacitor Cst or the like.

In the non-emission area NEA, a repair pattern RP is further disposed to repair the signal lines of the sub-pixels SP1, SP2, SP3, and SP4 when a defect such as a short or open circuit occurs in the signal lines. The repair pattern RP may be prepared to repair the reference voltage line RL.

The repair pattern RP may have at least one area disposed to overlap the reference voltage line RL and may be connected to the repair pattern RP through a contact hole in the overlapping area. The repair pattern RP may include a plurality of extensions extending in the row direction X, and each extension may be connected to one side of the branch line BL through the contact hole. The repair pattern RP may be connected to each of the sub-pixels SP1, SP2, SP3, and SP4 through the extensions.

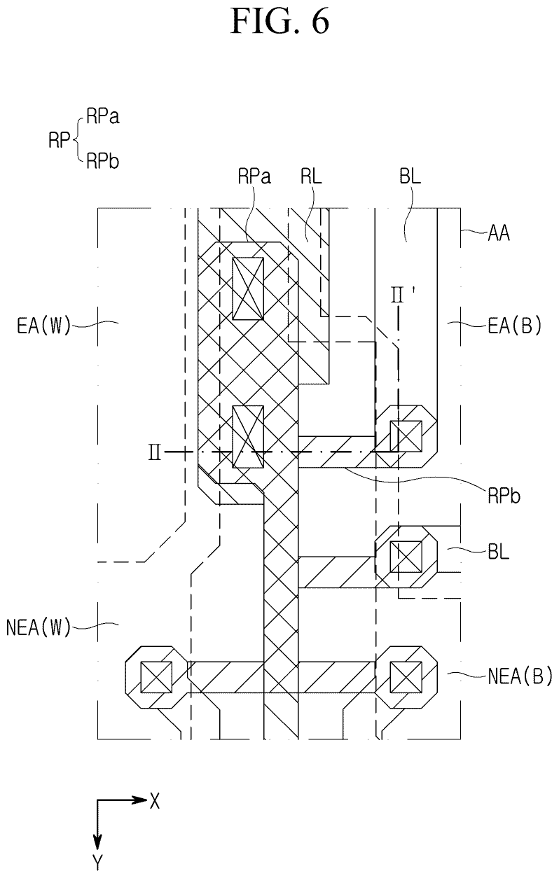

A structure of the repair pattern RP will be described in more detail below with reference to FIG. 6.

The emission area EA is an area which may independently emit light of one color and may be an area where the light emitting device LD (see FIG. 2) is disposed.

Specifically, an anode electrode AE of the light emitting device LD may be disposed in the emission area EA. When the light emitting device LD is a bottom emitting type, the anode electrode AE is formed as a transparent electrode capable of transmitting light. Conversely, when the light emitting device LD is a top emitting type, the anode electrode AE may be formed as an opaque electrode. In the following embodiments, it is assumed that the light emitting device LD is a bottom emitting type.

A bank (not shown) is further formed on the anode electrode AE to cover an edge of the anode electrode AE and expose a central area upward. The area of the anode electrode AE which is not covered by the bank and is exposed upward can be defined as the emission area EA.

The anode electrode AE may be formed in the emission area EA and may extend to the non-emission area NEA to be connected to the second electrode DT2 of the driving transistor DT in the non-emission area NEA. The anode electrode AE may be connected to the second electrode DT2 of the driving transistor DT through a via hole.

A light emitting layer and a cathode electrode (not shown) may be further formed on the anode electrode AE.

Color filters CF1, CF2, and CF3 for converting light generated from the light emitting device LD may be further disposed in the emission area EA. When the light emitting device LD is a bottom emitting type, the color filters CF1, CF2, and CF3 may be formed on a layer under the light emitting device LD.

The color filters CF1, CF2, and CF3 may include the first color filter CF1, the second color filter CF2, and the third color filter CF3. For example, the first color filter CF1 may be a red color filter for transmitting only red light and shielding light of other colors. The second color filter CF2 may be a blue color filter for transmitting only blue light and shielding light of other colors. The third color filter CF3 may be a green color filter for transmitting only green light and shielding light of other colors.

Each of the color filters CF1, CF2, and CF3 may be disposed in the emission area EA of each of the corresponding sub-pixels SP1, SP3, and SP4. For example, the first color filter CF1 may be disposed in the emission area EA of the first sub-pixel SP1, the second color filter CF2 may be disposed in the emission area EA of the third sub-pixel SP3, and the third color filter CF3 may be disposed in the emission area EA of the fourth sub-pixel SP4.

In one embodiment, the color filters CF1, CF2, and CF3 may not be disposed in the emission area EA of the second sub-pixel SP2 displaying white. Specifically, when the light emitting device LD emits white light, the second sub-pixel SP2 displaying white does not require the color filters CF1, CF2, and CF3 for converting the light generated by the light emitting device LD. Therefore, separate color filters CF1, CF2, and CF3 may not be disposed in the emission area EA of the second sub-pixel SP2.

The color filters CF1, CF2, and CF3 may be disposed in the emission area EA of each of the corresponding sub-pixels SP1, SP3, and SP4 and extend to a portion of the non-emission area NEA in which the reference voltage line RL and/or the gate line GL are disposed beyond the emission area EA. For example, the second color filter CF2 of the third sub-pixel SP3 disposed adjacent to the repair pattern RP may be disposed to cover the repair pattern RP in the non-emission area NEA. The second color filter CF2 may extend to the non-emission areas NEA of other adjacent sub-pixels SP2 and SP4 other than the third sub-pixel SP3.

In the embodiment, the second color filter CF2 may be used to shield the laser used in the pixel repair process from being transmitted to the upper light emitting device LD. Specifically, when the laser process is performed for pixel repair, a laser in a specific wavelength band may be radiated to the sub-pixels SP1, SP2, SP3, and SP4. The laser used at this time may cause damage to the anode electrode AE or the cathode electrode of the light emitting device LD disposed at the top. Therefore, the second color filter CF2 can be used to prevent the laser from passing through the circuit devices and reaching the light emitting device LD.

For example, a laser with a green wavelength band can be used for pixel repair. In the second sub-pixel SP2 in which the color filters CF1, CF2, and CF3 are not disposed, the laser may reach the light emitting device LD to cause a defect in the light emitting device LD. In the embodiment, the second color filter CF2 adjacent to the second sub-pixel SP2 may extend to the non-emission area NEA of the second sub-pixel SP2 to block repair damage. In this case, the second color filter CF2 may be disposed to overlap at least one area of the repair pattern RP in the non-emission area NEA of the second sub-pixel SP2.

Similarly, in the fourth sub-pixel SP4 in which the third color filter CF3 for transmitting green light is disposed, the laser may reach the light emitting device LD to cause a defect in the light emitting device LD. In the embodiment, the second color filter CF2 for transmitting only blue light may be further formed on the repair area of the fourth sub-pixel SP4 to block repair damage. In this case, the second color filter CF2 may be disposed to cover the repair pattern RP in the non-emission area NEA of the fourth sub-pixel SP4.

FIG. 6 is an enlarged view of area AA shown in FIG. 5. Specifically, FIG. 6 shows the repair pattern RP connected to the reference voltage line RL.

When a defective pixel, such as a short or open circuit of the signal line, occurs in the display panel 50, a repair process may be performed on the corresponding pixel. The repair process may be performed in a method of making the signal line dark spots by cutting the signal line of the defective pixel with a laser. For example, when a defect occurs in the reference voltage line RL, the reference voltage line RL and the sub-pixels SP1, SP2, SP3, and SP4 may be disconnected to make the corresponding sub-pixels SP1, SP2, SP3, and SP4 dark spots.

To disconnect the reference voltage line RL and the sub-pixels SP1, SP2, SP3, and SP4, the branch line BL connected to the reference voltage line RL may be cut with a laser. When the branch line BL is made of an opaque material, the branch line BL does not transmit the laser and may be cut by absorbing the energy of the laser.

On the other hand, as described above, when the branch line BL is made of a transparent material, the branch line BL may not absorb the energy of the laser and transmits the laser as it is, and thus the repair process may not be performed. Therefore, as shown in FIGS. 3 to 6, the transparent branch line BL may be connected to the reference voltage line RL through the repair pattern RP formed of an opaque conductive layer. In the embodiment, the repair pattern RP is cut by being irradiated with the laser, thereby disconnecting the branch line BL and the reference voltage line RL.

Specifically, the repair pattern RP may include a body portion RPa disposed to have at least one area overlapping the reference voltage line RL and connected to the reference voltage line RL through a contact hole. In addition, the repair pattern RP may include extensions RPb extending by being branched from the body portion RPa and connected to the branch line BL through a contact hole. The extensions RPb may have a smaller width than the body portion RPa, and thus may be easily cut through a laser.

The extensions RPb slightly extend, for example, in the row direction X. Some of the extensions RPb have one ends connected to the body portion RPa and the other ends connected to the corresponding branch line BL. Some of the extensions RPb may be connected to the corresponding sub-pixels SP1 and SP4 through branch line BL. Here, the corresponding sub-pixels SP1 and SP4 may be the sub-pixels SP1 and SP4 disposed far from the reference voltage line RL in the unit pixel PX.

The others of the extensions RPb may have one ends connected to the body portion RPa and the other ends directly connected to the second electrode T22 of the second transistor T2 of the corresponding sub-pixels SP2 and SP3. Here, the corresponding sub-pixels SP2 and SP3 may be the sub-pixels SP2 and SP3 disposed close to the reference voltage line RL in the unit pixel PX.

In one embodiment, the extensions RPb connected to the first, third, and fourth sub-pixels SP1, SP3, and SP4 extend in the row direction X from one side of the body portion RPa. In other words, the extensions RPb connected to the first, third, and fourth sub-pixels SP1, SP3, and SP4 are disposed in the third sub-pixel SP3 disposed at one side of the body portion RPa (i.e., one side of the reference voltage line RL).

In one embodiment, the extension RPb connected to the second sub-pixel SP2 extends in the row direction X from the other side of the body portion RPa. In other words, the extension RPb connected to the second sub-pixel SP2 may be disposed in the second sub-pixel SP2 disposed at the other side of the body portion RPa (i.e., the other side of the reference voltage line RL). When an aperture ratio of the second sub-pixel SP2 is not reduced, the extension RPb connected to the second sub-pixel SP2 may extend to the non-emission area NEA of the second sub-pixel SP2 and may be connected to the second transistor T2 of the sub-pixel SP2.

During the pixel repair process, the extensions RPb may be cut with a laser to disconnect the reference voltage line RL and the sub-pixels SP1, SP2, SP3, and SP4. In this case, to prevent damage to the upper light emitting device LD due to the laser, the extensions RPb of the repair pattern RP may be covered by the second color filter CF2.

As described above with reference to FIGS. 3 to 6, in the display device 1 according to one embodiment, the third sub-pixel SP3 displaying blue is designed to have an asymmetric structure for pixel repair.

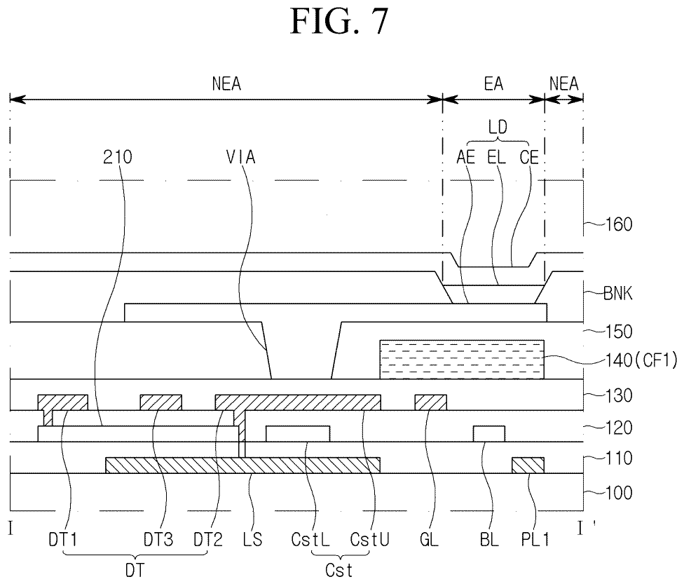

FIG. 7 is one embodiment of a cross-sectional view along line I-I′ in FIG. 5.

Referring to FIG. 7, the sub-pixel SP1 includes a substrate 100, a circuit device layer which is disposed on the substrate 100 and on which circuit devices are disposed, and a light emitting device layer which is disposed above the circuit device layer and on which the light emitting devices LD are disposed.

The substrate 100 may be a base substrate on which the circuit devices and the light emitting devices LD are disposed and may be a light transmissive substrate. The substrate 100 may be a rigid substrate including glass or tempered glass, or a flexible substrate made of plastic.

A first conductive layer may be formed on the substrate 100. The first conductive layer may include lines for driving the sub-pixel SP1. For example, the first conductive layer may include the first power line PL1 and may further include the data line DL (not shown) and the reference voltage line RL (not shown). In one embodiment, the first conductive layer may further include the light shielding layer LS disposed to overlap the driving transistor DT. The first conductive layer may be made of a conductive material, such as copper (Cu), aluminum (Al), molybdenum (Mo), nickel (Ni), titanium (Ti), chromium (Cr), or an alloy thereof, but is limited thereto.

A buffer layer 110 may be formed on the first conductive layer. The buffer layer 110 can prevent ions or impurities from diffusing from the substrate 100 and block moisture permeation. In addition, the buffer layer 110 can improve the surface flatness of the substrate 100. The buffer layer 110 may include an inorganic material, such as oxide or nitride, an organic material, or an organic-inorganic composite and may be formed in a single-layer or multi-layer structure. For example, the buffer layer 110 may have a triple layer or more structure made of silicon oxide, silicon nitride, and silicon oxide.

An active layer 210 may be formed on the buffer layer 110. The active layer 210 may be made of a silicon-based semiconductor material or an oxide-based semiconductor material. Amorphous silicon or polycrystalline silicon can be used as the silicon-based semiconductor material. As oxide-based semiconductor materials, indium tin gallium zinc oxide (InSnGaZnO) which is quaternary metal oxide, indium gallium zinc oxide (InGaZnO), indium tin zinc oxide (InSnZnO), indium aluminum zinc oxide (InAlZnO), tin gallium zinc oxide (SnGaZnO), aluminum gallium zinc oxide (AlGaZnO), tin aluminum zinc oxide (SnAlZnO), which are ternary metal oxides, indium zinc oxide (InZnO), tin zinc oxide (SnZnO), aluminum zinc oxide (AlZnO), zinc magnesium oxide (ZnMgO), tin magnesium oxide (SnMgO), indium magnesium oxide (InMgO), indium gallium oxide (InGaO), indium oxide (InO), tin oxide (SnO), zinc oxide (ZnO), which are binary metal oxides, and the like can be used.

The active layer 210 may include a source area and a drain area containing p-type or n-type impurities, and a channel area formed between the source area and the drain area.

At least one area of the active layer 210 may be made of a transparent material. The transparent material is, for example, transparent oxide and may be a transparent conductive material, such as tin oxide (TO), indium tin oxide (ITO), indium zinc oxide (IZO), or indium tin zinc oxide (ITZO), but is not limited thereto. For example, the branch line BL formed on the active layer 210 may be made of a transparent material.

The active layer 210 may further include the lower electrode CstL of the storage capacitor Cst.

An interlayer insulating layer 120 may be formed on the active layer 210. The interlayer insulating layer 120 may be silicon oxide (SiOx), silicon nitride (SiNx), or a multilayer thereof.

A second conductive layer is formed on the interlayer insulating layer 120. The second conductive layer may be an electrode layer on which electrodes of circuit devices forming the sub-pixel SP1 are disposed. For example, the second conductive layer may include the drain/source electrodes DT1 and DT2 and the gate electrode DT3 of the transistor. The gate electrode DT3 may be disposed to overlap the channel area of the corresponding active layer 210, and the drain/source electrodes DT1 and DT2 may be connected to the drain area and the source area of the active layer 210, respectively, through contact holes. The drain/source electrodes DT1 and DT2, the gate electrode DT3, and the corresponding active layer 210 corresponding thereto may form one transistor DT. In the shown embodiment, the driving transistor DT connected to the light emitting device LD is shown as an example.

In addition, the second conductive layer may further include the upper electrode CstU of the storage capacitor Cst.

In addition, the second conductive layer may include lines for driving the sub-pixel SP1. For example, the second conductive layer may include the gate line GL. The second conductive layer may be made of a conductive material, such as copper (Cu), aluminum (Al), molybdenum (Mo), nickel (Ni), titanium (Ti), chromium (Cr), or an alloy thereof, but is limited thereto.

In one embodiment, the second conductive layer may further include the repair pattern RP for pixel repair.

A passivation layer 130 is formed on the second conductive layer. The passivation layer 130 may be an insulating layer for protecting components below the passivation layer 113. The passivation layer 130 may be formed in a single layer or a multiple layer of silicon oxide (SiOx) or silicon nitride (SiNx), but is not limited thereto.

A color filter layer 140 is formed on the passivation layer 130. The color filter layer 140 may include the red color filter CF1, the blue color filter CF2, and the green color filter CF3. Specifically, the red color filter CF1 may be disposed on the emission area EA of the red sub-pixel SP1, the blue color filter CF2 may be disposed on the emission area EA of the blue sub-pixel SP3, and the green color filter CF3 may be disposed on the emission area EA of the green sub-pixel SP4. The color filter may not be disposed in the white sub-pixel SP2.

An overcoat layer 150 may be formed on the color filter layer 140. The overcoat layer 150 may be a planarization film for reducing a step of a lower structure. The overcoat layer 150 may be made of an organic material and for example, formed in a single layer or a double layer of polyimide or photo acryl, but is not limited thereto.

The light emitting device layer is formed on the overcoat layer 150 and includes the light emitting devices LD. The light emitting device LD includes the anode electrode AE, an emission layer EL, and a cathode electrode CE.

The anode electrode AE is formed on the overcoat layer 150. The anode electrode AE is connected to the second electrode DT2 of the driving transistor DT through a via hole passing through the overcoat layer 150.

A bank BNK is further formed on the overcoat layer 150. The bank BNK is formed to cover an edge of the anode electrode AE.

The emission layer EL is formed on the anode electrode AE. The emission layer EL is formed on an uncovered and exposed area of the anode electrode AE by the bank BNK. The area of the anode electrode AE which is not covered and is exposed by the bank BNK can be defined as the emission area EA.

The cathode electrode CE is widely deposited on the substrate 100. The cathode electrode CE is formed on the emission layer EL and the bank BNK. In other words, the cathode electrode CE may be formed to cover the emission layer EL and the bank BNK.

An encapsulation layer 160 may be formed on the cathode electrode CE. The encapsulation layer 160 can prevent oxygen or moisture from penetrating into the plurality of light emitting devices LD by including at least one inorganic layer. The encapsulation layer 160 can protect the plurality of light emitting devices LD from foreign substance such as dust by including at least one organic layer.

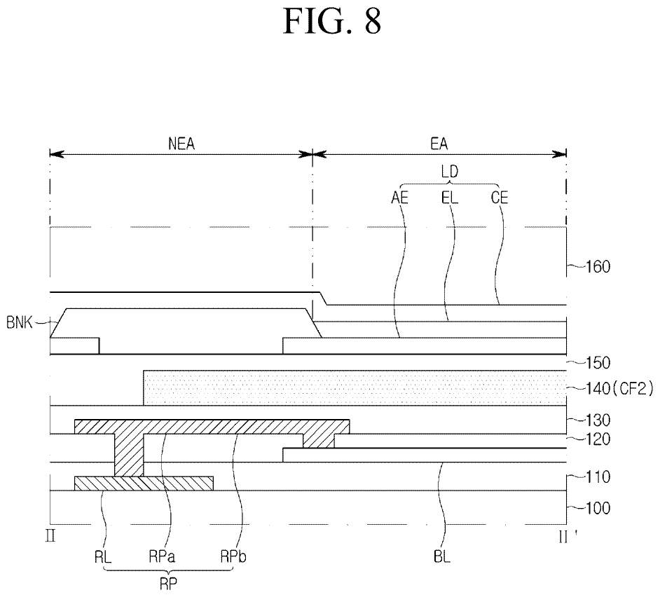

FIG. 8 is one embodiment of a cross-sectional view along line II-II′ in FIG. 6. In describing FIG. 8, the same reference numerals are given to components overlapping those of FIG. 7, and detailed description thereof is omitted.

Referring to FIG. 8, the first conductive layer may be formed on the substrate 100. The first conductive layer may include lines for driving the sub-pixel SP3. For example, the first conductive layer may include the reference voltage line RL.

The buffer layer 110 may be formed on the first conductive layer. The buffer layer 110 can prevent ions or impurities from diffusing from the substrate 100 and block moisture permeation. In addition, the buffer layer 110 can improve the surface flatness of the substrate 100.

The active layer 210 may be formed on the buffer layer 110. The active layer 210 may include the branch line BL. The branch line BL has at least a portion formed to overlap the emission area EA. The branch line BL may be made of a transparent material. The transparent material is, for example, transparent oxide and may be a transparent conductive material, such as tin oxide (TO), indium tin oxide (ITO), indium zinc oxide (IZO), or indium tin zinc oxide (ITZO), but is not limited thereto.

The interlayer insulating layer 120 may be formed on the active layer 210.

The second conductive layer is formed on the interlayer insulating layer 120. The second conductive layer may be an electrode layer on which electrodes of circuit devices forming the sub-pixel SP3 are disposed.

In one embodiment, the second conductive layer may further include the repair pattern RP for pixel repair. The repair pattern RP may include the body portion RPa disposed to have at least one area overlapping the reference voltage line RL and connected to the reference voltage line RL through the contact hole. In addition, the repair pattern RP may include the extension RPb extending from the body portion RPa. The extension RPb may has one end connected to the body portion RPa and the other end connected to the corresponding branch line BL.

The passivation layer 130 is formed on the second conductive layer. The passivation layer 130 may be an insulating layer for protecting components below the passivation layer 113.

The color filter layer 140 is formed on the passivation layer 130. The color filter layer 140 may include the red color filter CF1, the blue color filter CF2, and the green color filter CF3. Specifically, the red color filter CF1 may be disposed on the emission area EA of the red sub-pixel SP1, the blue color filter CF2 may be disposed on the emission area EA of the blue sub-pixel SP3, and the green color filter CF3 may be disposed on the emission area EA of the green sub-pixel SP4. The color filter may not be disposed in the white sub-pixel SP2.

The color filters CF1, CF2, and CF3 may extend to a portion of the non-emission area NEA. For example, the second color filter CF2 may be formed to overlap at least one area of the repair pattern RP disposed in the non-emission area NEA. In particular, the second color filter CF2 may be further formed on the extension RPb of the repair pattern RP cut with a laser upon pixel repair.

The overcoat layer 150 may be formed on the color filter layer 140. The overcoat layer 150 may be a planarization film for reducing a step of a lower structure.

The light emitting device layer is formed on the overcoat layer 150 and includes the light emitting devices LD. The light emitting device LD includes the anode electrode AE, the emission layer EL, and the cathode electrode CE.

The anode electrode AE is formed on the overcoat layer 150. The bank BNK is further formed on the overcoat layer 150. The bank BNK is formed to cover an edge of the anode electrode AE.

The emission layer EL is formed on the anode electrode AE. The emission layer EL is formed on the uncovered and exposed area of the anode electrode AE by the bank BNK. The area of the anode electrode AE which is not covered and is exposed by the bank BNK can be defined as the emission area EA.

The cathode electrode CE is widely deposited on the substrate 100. The cathode electrode CE is formed on the emission layer EL and the bank BNK. In other words, the cathode electrode CE may be formed to cover the emission layer EL and the bank BNK.

An encapsulation layer 160 may be formed on the cathode electrode CE. The encapsulation layer 160 can prevent oxygen or moisture from penetrating into the plurality of light emitting devices LD by including at least one inorganic layer. The encapsulation layer 160 can protect the plurality of light emitting devices LD from foreign substance such as dust by including at least one organic layer.

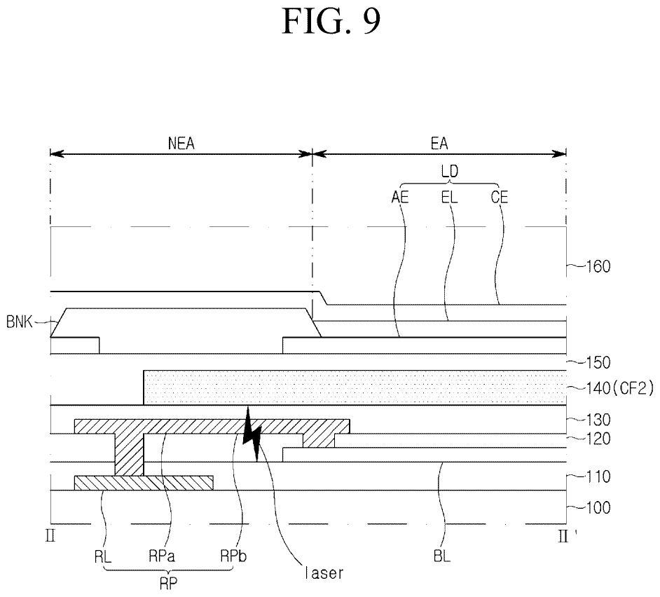

FIG. 9 is a cross-sectional view for describing a pixel repair method according to one embodiment.

As described above with reference to FIG. 3, in the present invention, the reference voltage line RL is shared between the four sub-pixels SP1, SP2, SP3, and SP4. In this case, the branch line BL may be provided to connect the reference voltage line RL to each of the sub-pixels SP1, SP2, SP3, and SP4. When the branch line BL is made of an opaque material, the branch line BL should be disposed in the non-emission area NEA, which reduces the aperture ratios of the sub-pixels SP1, SP2, SP3, and SP4. In one embodiment, to increase the aperture ratios of the sub-pixels SP1, SP2, SP3, and SP4, the branch line BL is made of a transparent material to be disposed in the emission area EA.

As a result, in the embodiment, it is possible to secure the sufficient aperture ratios of the sub-pixels SP1, SP2, SP3, and SP4 by forming the branch line BL made of a transparent material and changing the shape thereof.

As the branch line BL is made of a transparent material, the laser cutting and pixel repair for the branch line BL cannot be applied correctly. Therefore, in one embodiment, the repair pattern RP for connecting the branch line BL with the reference voltage line RL is further formed. The repair pattern RP may include the body portion RPa connected to the reference voltage line RL and extensions RPb extending from the body portion RPa and connected to the branch line BL. The extensions RPb of the repair pattern RP may have a smaller width and may be easily cut with a laser. As shown in FIG. 9, when the laser is radiated to the extensions RPb, the extensions RPb absorbing the energy of the laser may be cut to make the defective sub-pixel dark spots.

In one embodiment, the extensions RPb connected to the sub-pixels SP1, SP3, and SP4 may be disposed at one side of the body portion RPa. For example, the extensions RPb may all be disposed on the blue sub-pixel SP3. In the embodiment, the laser cutting for the sub-pixels SP1, SP3, and SP4 may be performed collectively in the non-emission area NEA of the third sub-pixel SP3.

In one embodiment, the extensions RPb connected to the white sub-pixel SP2 may be disposed at the other side of the body portion RPa. For example, the extension RPb connected to the white sub-pixel SP2 may be disposed in the non-emission area NEA of the white sub-pixel SP2.

As shown in FIG. 9, when the laser is radiated to the extensions RPb, damage caused by the laser may be applied to the upper light emitting device LD. To prevent this, the color filter CF2 is used. When the extension RPb of the repair pattern RP is disposed on the blue sub-pixel SP3, the blue color filter CF2 is disposed to cover the extension RPb, thereby blocking the laser from reaching the light emitting device LD and enabling stable repair.

When at least one (e.g., the extension RPb connected to the white sub-pixel SP2) of the extensions RPb is disposed on another sub-pixel SP2, the blue color filter CF2 may extend to the area of the corresponding sub-pixel SP2. For example, the blue color filter CF2 may extend to the non-emission area NEA of the white sub-pixel SP2 to cover the extension RPb disposed on the white sub-pixel SP2. Since the extension RPb is disposed in the non-emission area NEA of the white sub-pixel SP2, the blue color filter CF2 does not need to extend to the emission area EA of the white sub-pixel SP2. In other words, it is possible to reduce the area where the blue color filter CF2 is disposed, thereby securing the sufficient aperture ratio of the white sub-pixel SP2.

According to the display device according to the embodiments, by constituting the branch line connected to the reference voltage line made of a transparent material and changing the shape, it is possible to adjust the location of the repair area for the signal line and maximally secure the opening area.

According to the display device according to the embodiments, it is possible to reduce the area of the color filter disposed for pixel repair and at the same time, prevent short defect which can occur while the repair process is performed.

According to the display device according to the embodiments, it is possible to secure the high aperture ratio and stably perform the repair process for the signal line.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display device, comprising:
a substrate which includes an emission area of a sub-pixel and a non-emission area and on which a plurality of sub-pixels are disposed;
a gate line disposed in the non-emission area and extending in one direction;
a signal line disposed in the non-emission area and intersecting the gate line;
a repair pattern disposed in the non-emission area and connected to the signal line; and
at least one branch line for connecting the repair pattern with circuit devices of the plurality of sub-pixels.

2. The display device of claim 1, wherein the at least one branch line is made of a transparent material.

3. The display device of claim 1, wherein at least one area of the at least one branch line overlaps the emission areas of the plurality of sub-pixels.

4. The display device of claim 1, wherein the repair pattern includes:
a body portion connected to the signal line; and
a plurality of extensions extending in one direction from the body portion and connected to the plurality of sub-pixels, respectively.

5. The display device of claim 4, wherein at least some of the plurality of extensions are connected to the plurality of sub-pixels, respectively, through the at least one branch line.

6. The display device of claim 4, wherein at least some of the plurality of extensions extend from one side of the body portion and disposed in a first color sub-pixel disposed at one side of the body portion.

7. The display device of claim 6, wherein the others of the plurality of extensions extend from the other side of the body portion and disposed in a second color sub-pixel disposed at the other side of the body portion.

8. The display device of claim 4, wherein the plurality of extensions are cut with a laser upon pixel repair.

9. The display device of claim 4, further comprising a color filter layer disposed in the emission area and extending to the non-emission area to cover at least one area of the repair pattern.

10. The display device of claim 9, wherein the color filter layer includes a first color filter formed in the emission area of a first color sub-pixel disposed at one side of the repair pattern and extending to the non-emission areas of adjacent sub-pixels of the first color sub-pixel.

11. The display device of claim 10, wherein the first color filter covers at least one of the plurality of extensions of the repair pattern in the non-emission area of an adjacent second color sub-pixel.

12. The display device of claim 11, wherein the first color sub-pixel is a blue sub-pixel, the second color sub-pixel is a white sub-pixel, and the first color filter is a blue color filter.

13. The display device of claim 1, further comprising:
a first conductive layer formed on the substrate and including the signal line;
a buffer layer formed on the first conductive layer;
an active layer formed on the buffer layer and including the at least one branch line;
an interlayer insulating layer formed on the active layer; and
a second conductive layer formed on the interlayer insulating layer and including the gate line and the repair pattern.

14. A display device, comprising:
a substrate which includes an emission area and a non-emission area of a sub-pixel and on which a plurality of sub-pixels are disposed;
a gate line disposed in the non-emission area and extending in one direction;
a signal line disposed in the non-emission area and intersecting the gate line; and
a repair pattern disposed in the non-emission area and for connecting the signal line with circuit devices of the plurality of sub-pixels,
wherein the repair pattern includes:
a body portion connected to the signal line; and
a plurality of extensions extending in one direction from the body portion and connected to the plurality of sub-pixels, respectively.

15. The display device of claim 14, wherein at least some of the plurality of extensions extend from one side of the body portion and disposed in a blue color sub-pixel disposed at one side of the body portion.

16. The display device of claim 15, wherein the others of the plurality of extensions extend from the other side of the body portion and disposed in a white sub-pixel disposed at the other side of the body portion.

17. The display device of claim 16, comprising a blue color filter formed in the emission area of the blue sub-pixel disposed at one side of the body portion and extending to the non-emission areas of adjacent sub-pixels of the blue sub-pixel.

18. The display device of claim 17, wherein the blue color filter covers at least one of the plurality of extensions of the repair pattern in the non-emission area of an adjacent white sub-pixel.
